(19) United States
(12) Patent Application Publication
(10) Pub. No.: US 2023/0154847 A1
(43) Pub. Date: May 18, 2023

(54) ADVANCED STRUCTURES HAVING MOSFET TRANSISTORS AND METAL LAYERS

(71) Applicant: Fu-Chang Hsu, San Jose, CA (US)

(72) Inventor: Fu-Chang Hsu, San Jose, CA (US)

(21) Appl. No.: 18/055,397

(22) Filed: Nov. 14, 2022

Related U.S. Application Data
(60) Provisional application No. 63/280,119, filed on Nov. 16, 2021.

(51) Int. Cl. H01L 23/528; H01L 27/092; H01L 29/06; H01L 29/423; H01L 29/775; H01L 21/683; H01L 21/822; H01L 21/8238; H01L 29/66

(52) U.S. Cl. CPC H01L 23/5286; H01L 27/0922; H01L 29/0673; H01L 29/42392; H01L 29/775; H01L 21/6835; H01L 21/8221; H01L 21/823871; H01L 29/66439; H01L 2221/68372

(57) ABSTRACT

Advanced structures having MOSFET transistors and metal layers are disclosed. In one embodiment, a transistor structure is provided that includes a first transistor layer, a second transistor layer located under the first transistor layer, a first power bus layer located above the first transistor layer, a second power bus layer located under the second transistor layer, and a first interconnect layer located above the first power bus layer.

### CROSS-REFERENCE TO RELATED APPLICATIONS

This application claims the benefit of priority under 35 U.S.C. 119(e) based upon U.S. Provisional Patent application having Application No. 63/280,119 filed on Nov. 16, 2021 and entitled “Advanced MOSFET Transistors and Metal Layers Structure,” which is hereby incorporated herein by reference in its entirety.

### FIELD OF THE INVENTION

The exemplary embodiments of the present invention relate generally to the field of transistor devices, and more specifically to transistor cells, array structures, and associated processes.

### BACKGROUND OF THE INVENTION

The most advanced MOSFET transistor technology has been scaled down to below 3 nanometers (nm). However, when transistor size is reduced, the challenges in connecting such transistors to power buses and multiple metal-layer interconnections are significantly increased.

### SUMMARY

In various exemplary embodiments, advanced structures having MOSFETs (metal-oxide-semiconductor field-effect transistors) and metal layers are disclosed. In one embodiment, a novel configuration is provided that locates power buses and metal layer interconnections above and below one or more transistor layers. This effectively reduces the density of the metal layer patterns of the interconnections to relax pitch spacing and manufacturing challenges.

In an exemplary embodiment, a transistor structure is provided that includes a first transistor layer, a second transistor layer located under the first transistor layer, a first power bus layer located above the first transistor layer, a second power bus layer located under the second transistor layer, and a first interconnect layer located above the first power bus layer.

In an exemplary embodiment, a transistor structure is provided that includes a first transistor layer, a second transistor layer located below the first transistor layer, first and second power bus layers located between the first and second transistor layers, a first interconnect layer located above the first transistor layer, and a second interconnect layer located under the second transistor layer.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1 shows an embodiment of a structure comprising transistors and metal layers constructed according to the invention.

FIG. 2A shows a detailed embodiment of a MOSFET transistor structure constructed according to the invention.

FIG. 2B shows another embodiment of a MOSFET transistor structure constructed according to the invention.

FIG. 2C shows another embodiment of the MOSFET transistor structure constructed according to the invention using FinFET type of transistors.

FIG. 2D shows another embodiment of a MOSFET transistor structure constructed according to the invention using Forksheet type of transistors.

FIG. 2E shows another embodiment of a MOSFET transistor structure constructed according to the invention.

FIG. 2F shows another embodiment of a MOSFET transistor structure constructed according to the invention.

FIG. 2G shows another embodiment of a MOSFET transistor structure constructed according to the invention.

FIG. 2H shows another embodiment of a MOSFET transistor structure constructed according to the invention.

FIG. 2I shows another embodiment of a MOSFET transistor structure constructed according to the invention.

FIG. 2J shows another embodiment of a MOSFET transistor structure according to the invention.

FIGS. 3A-E show embodiments of process steps used to form the transistor structure shown in FIG. 1 according to the invention.

FIG. 4 shows another embodiment of structure having transistors and metal layers similar to the embodiment shown in FIG. 2F according to the invention.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, advanced MOSFET (metal-oxide-semiconductor field-effect transistor) and metal layers structure are disclosed. In one embodiment, a novel configuration is provided that locates power buses and metal layer interconnections on top and bottom of transistor structures. This effectively reduces the density of the metal layer patterns of the interconnections to relax pitch spacing and manufacturing challenges.

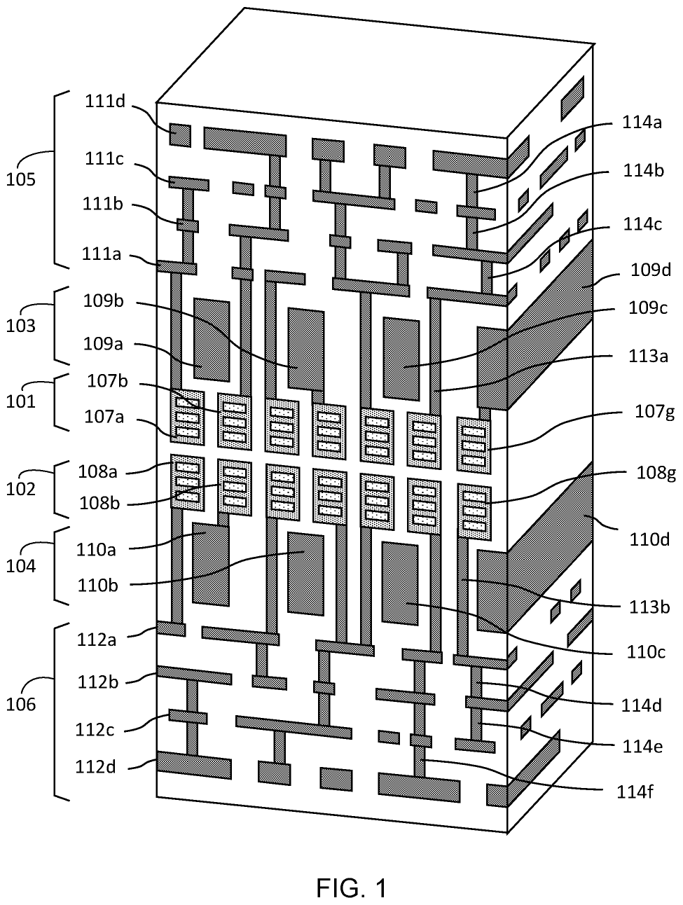

FIG. 1 shows an embodiment of a structure comprising transistors and metal layers constructed according to the invention. The structure comprises multiple layers with transistor layers 101 and 102 as shown. In another embodiment, the transistor layers comprise any number of layers. The structure shown in FIG. 1 use two transistor layers 101 and 102 as an example. Variations of the structure shown in FIG. 1 using any number of the transistor layers shall remain in the scope of the invention.

The transistor layers 101 and 102 comprise PMOS and/or NMOS transistors. The PMOS and NMOS transistors can be arranged in any orders. In one embodiment, the upper transistor layer 101 comprises PMOS transistors 107a to 107g and the lower transistor layer 102 comprises NMOS transistors 108a to 108g.

The layers 103 and 104 are power bus layers that are located above and below the transistor layers 101 and 102, respectively. The upper power bus layer 103 comprises metal power bus lines 109a to 109d and the lower power bus layer 104 comprises metal power bus lines 110a to 110d. In an implementation of a logic circuit, normally the sources of the PMOS and NMOS transistors are connected to VDD and VSS buses, respectively. Therefore, if the transistor layers 101 and 102 are PMOS and NMOS transistors, respectively, the power bus layers 103 and 104 are configured as VDD and VSS buses, respectively. If the transistor layers 101 and 102 are NMOS and PMOS transistors, respectively, the power bus layers 103 and 104 are configured as VSS and VDD buses, respectively. Please notice, the power bus layers 103 and 104 are located above and under the transistor layers 101 and 102, respectively. This arrangement makes it very easy to connect the transistor layers 101 and 102 to the power bus layers 103 and 104, respectively.

FIG. 1 also shows metal interconnections layers 105 and 106 that provide interconnections for the transistor layers 101 and 102, respectively. The metal interconnection layer 105 is located above the power bus layer 103 and above the transistor layer 101 and the metal interconnection layer 106 is located under the power bus layer 104 and under the transistor layer 102. This makes the connections of the transistor layers 101 and 102 to the metal interconnections layers 105 and 106 simple and efficient. The upper metal interconnection layer 105 comprises multiple metal layers, such as layers 111a to 111d and includes metal vias, such as vias 114a to 114c. The first metal layer 111a is connected to the transistor layer 101 through contacts, such as contact 113a.

The lower metal interconnections layer 106 comprises multiple metal layers, such as layers 112a to 112d and includes metal vias, such as vias 114d to 114f. The layers 112 of the lower metal interconnections layer 106 are connected to the transistor layer 102 through contacts, such as contact 113b.

The transistor and metal layer structure shown in FIG. 1 provides novel features. In conventional structures, both the PMOS and NMOS transistors are connected to metal layers on top of the structure. This increases the density of the connection patterns, especially for the first metal layer. The high-density connection pattern results in high cost for masks and complicated lithography steps used for multiple patterning. The high-density connection pattern also reduces the process yield.

In the transistors and metal layers structures shown in FIG. 1 constructed according to the invention, the PMOS transistors 101 are connected to the metal layer 111a that is located on top of the transistors 101, and the NMOS transistors 102 are connected to the metal layer 112a that is located under the transistors 102. This reduces the number of the metal layer connections of the metal layers 111a and 112a to approximately one half of the number of connections used in a conventional structure. This allows a larger pitch size to be used for the connection patterns in the metal layers 111a and 111b, which significantly reduces the cost of the masks and process steps and increases the yield.

Another novel feature provided by embodiments of the invention is that the number of the metal layers in 105 and 106 may be different. There is no limitation on the number of the layers in the metal layers 105 and 106. In one embodiment, the number of layers depends on the circuit and process requirements. For example, in one embodiment, the metal layers 105 and 106 comprise the same number of the metal layers. This embodiment can reduce the density of the metal patterns in each layer of the metal layers 105 and 106 by approximately one half of the number of layers used in the conventional structure in which all the metal layers are located on top of the transistors 101 and 102. In another embodiment, the metal layers 106 under the transistors 102 comprise only one metal layer (e.g., metal layer 112a). This can reduce the density of the metal patterns in the first metal layers 111a and 112a by approximately one half of the number of layers used in the conventional structure in which all the metal layers are located on top of the transistors 101 and 102. In this exemplary embodiment, the density of the metal layers 111b to 111d remain unchanged.

Accordingly, in various embodiments, a transistor structure is disclosed that comprises a first transistor layer, a second transistor layer located under the first transistor layer, a first power bus layer located above the first transistor layer, a second power bus layer located under the second transistor layer, and a first interconnect layer located above the first power bus layer.

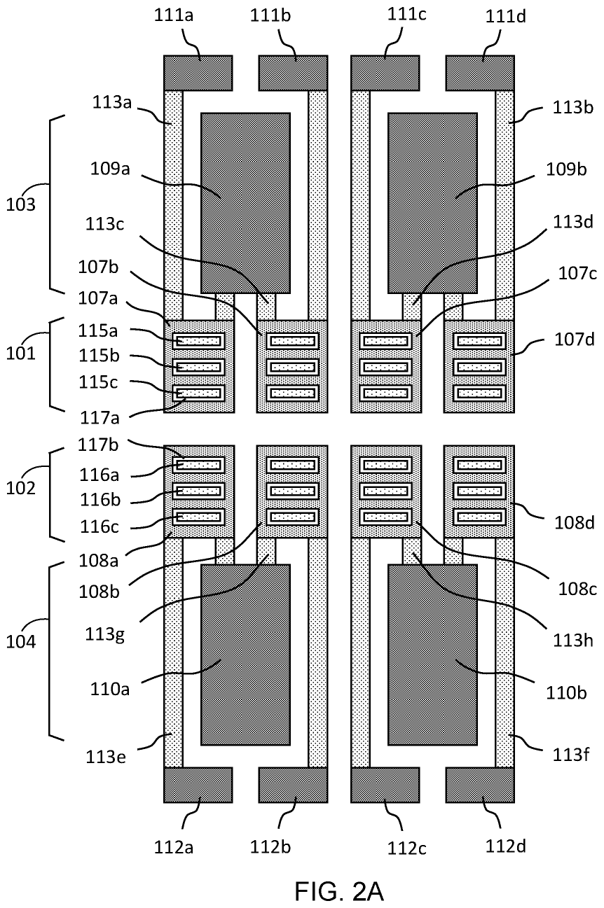

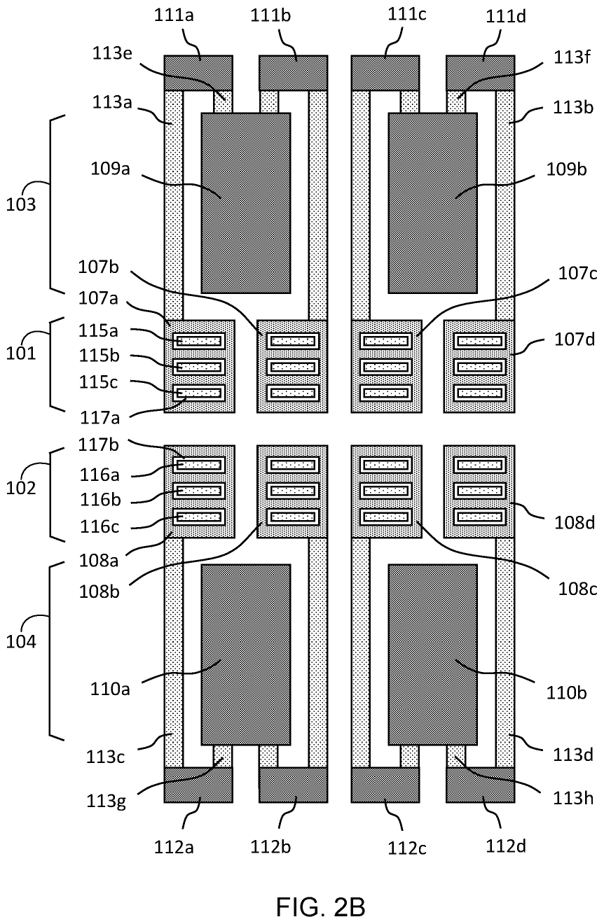

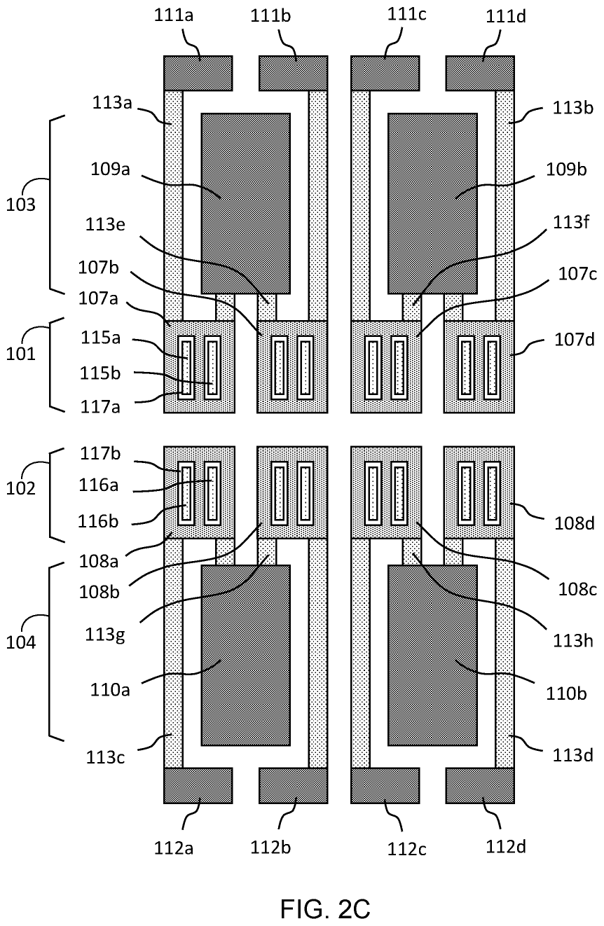

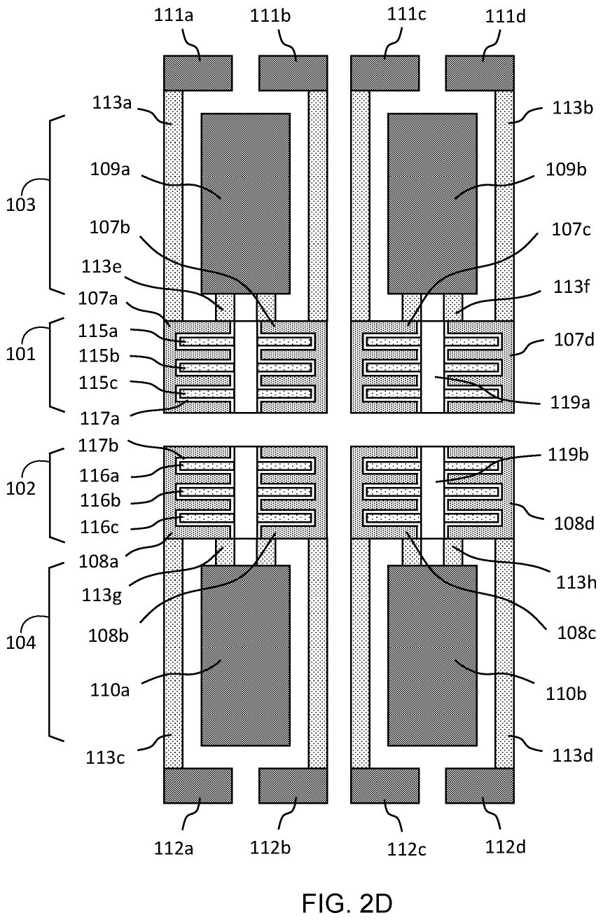

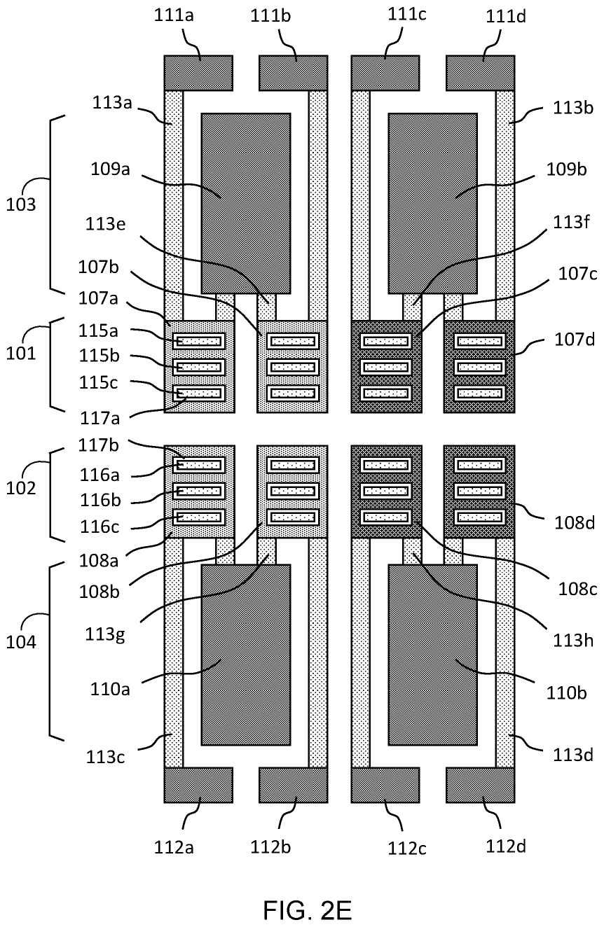

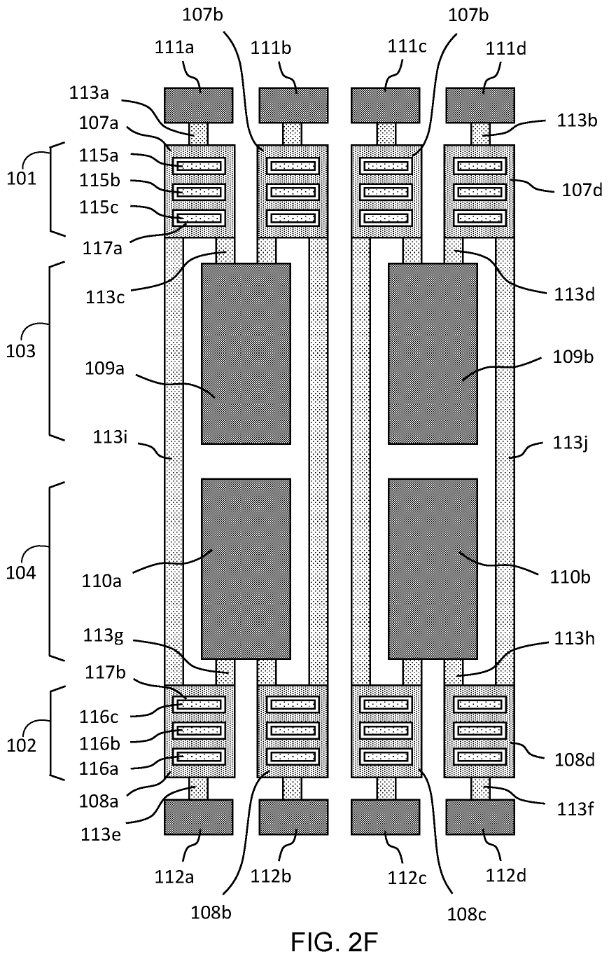

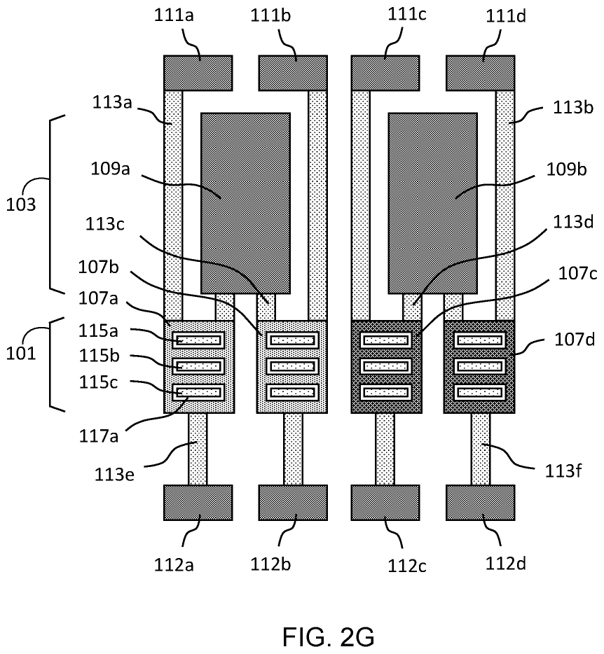

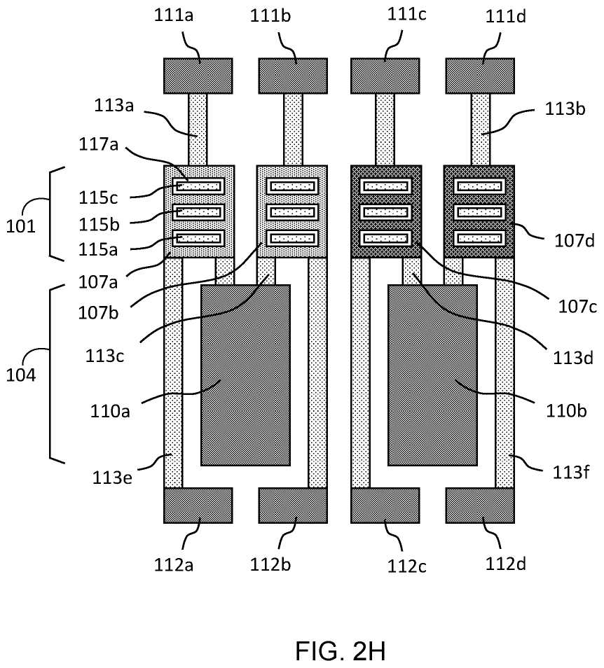

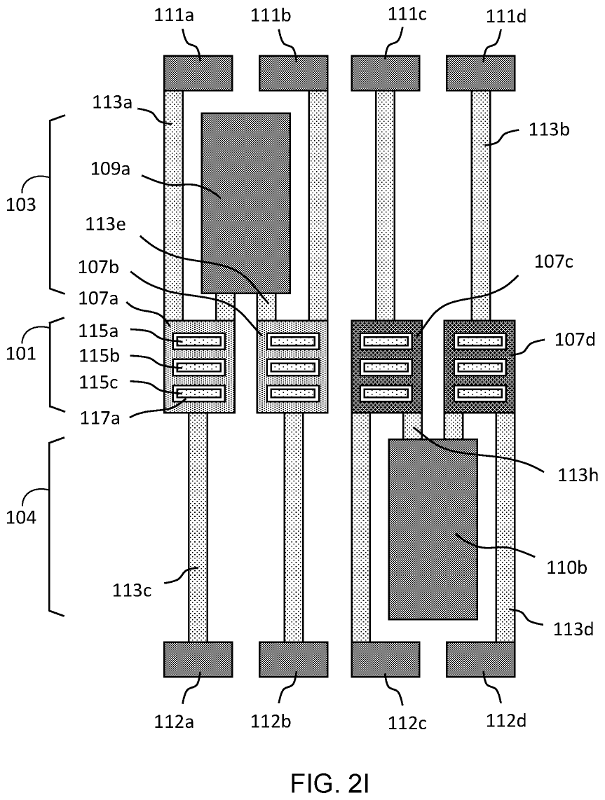

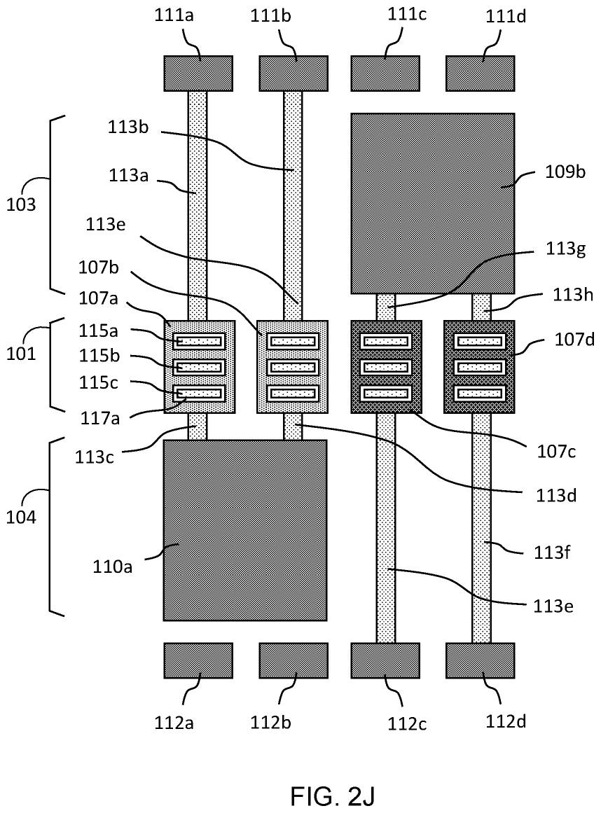

FIG. 2A shows a detailed embodiment of a MOSFET transistor structure shown in FIG. 1 and constructed according to the invention. For clarity and ease of description, only the metal layers 111a to 111d and 112a to 112d are shown. The upper metal layers 111b-d and lower metal layers 112b-d and associated vias are not shown in FIG. 2A.

The transistors 101 and 102 comprise any type of transistors, such as gate-all-around (GAA) transistors, Nanosheet transistors, multiple-bridge channel (MBC) transistors, FinFET transistors, Forksheet transistors, or any other suitable transistor type. There is no limitation of the type of the transistors to which the invention may be applied.

FIG. 2A shows an embodiment of a transistor structure constructed using multiple-bridge channel (MBC) type of transistors according to the invention. Multiple silicon layers 115a to 115c and 116a to 116c form the channels of the transistors. Although three channels per transistor are shown as an example, any number of channels can be used for each transistor. The channels are covered by a gate dielectric layer, such as layers 117a and 117b formed of a thin layer of oxide or high-K material, such as HfO2. Gates 107a to 107d and gates 108a to 108d are the gates of the transistors formed of conductor material, such as metal or heavily doped semiconductor material, such as polysilicon, germanium, or gallium arsenide, or other suitable material. Depending on the process technology, PMOS transistors and NMOS transistors may have different types of metal gate material. For example, in one embodiment, the gates of the PMOS transistors are formed of titanium nitride (TiN), and the gates of the NMOS transistors are formed of titanium-aluminum nitride (TiAlN).

The upper-layer transistors 107a to 107d are connected to the metal layers 111a to 111d through contacts, such as contacts 113a and 113b, or to power bus lines 109a and 109b through contacts, such as contacts 113c and 113d. Similarly, the lower-layer transistors 108a to 108d are connected to the metal layers 112a to 112d through contacts, such as contacts 113e and 113f, or to power bus lines 110a and 110b through contacts, such as contacts 113g and 113h.

In the structure shown in FIG. 2A, the upper-layer transistors 107a to 107d are connected to the metal layers 111a to 111d located above the transistors, and the lower-layer transistors 108a to 108d are connected to the metal layer 112a to 112d located under the transistors. Therefore, the density of the metal layers 111a to 111d and 112a to 112d are reduced to approximately one half of the metal layer density of conventional structures.

FIG. 2B shows another embodiment of a MOSFET transistor structure constructed according to the invention. This embodiment is similar to the embodiment shown in FIG. 2A except that the power bus contacts, such as contacts 113e and 113f, are located on top of the power bus lines 109a and 109b, and the power bus contacts, such as contacts 113g and 113h, are located below the power bus lines 110a and 110b.

FIG. 2C shows another embodiment of the MOSFET transistor structure constructed according to the invention using FinFET type of transistors. This embodiment is similar to the embodiment shown in FIG. 2A except that the channels, such as channels (115a, 115b) and (116a, 116b) are formed by using a FinFET process. Although the embodiment shown in FIG. 2C shows two channels per transistor for illustration, other embodiments can have any number of channels for each transistor.

FIG. 2D shows another embodiment of a MOSFET transistor structure constructed according to the invention using Forksheet type of transistors. This embodiment is similar to the embodiment shown in FIG. 2A except that the channels, such as channels (115a, 115b) and (116a, 116b) are formed by using a Forksheet transistor process. Although the example shows three channels per transistor for illustration, other embodiments can have any number of channels for each transistor. The insulating layers 119a and 119b comprise an insulating material, such as oxide, and formed between gates 107c and 107d to separate gates 107c and 107d and formed between gates 108c and 108d to separate gates 108c and 108d, respectively.

Although the embodiment shown in FIG. 2A is configured so that the upper-layer transistors 107a to 107d are PMOS transistors and the lower-layer transistors 108a to 108d are NMOS transistors, the PMOS and NMOS transistors the arrangement of the transistors can be configured in any other way.

FIG. 2E shows another embodiment of a MOSFET transistor structure constructed according to the invention. This embodiment is similar to the embodiment shown in FIG. 2A except that the transistors 107a, 107b, 108a, and 108b are PMOS transistors and the transistors 107c, 107d, 108c, and 108d are NMOS transistors. For clarity, the gates of the PMOS and NMOS transistors are shown in FIG. 2E using different shading. The power bus is arranged accordingly, such that the top power bus lines 109a and 110a are configured as a VDD bus and the bottom power bus lines 109b and 110b are configured as a VSS bus.

In addition to the embodiments shown and described herein, there are many other ways to arrange the PMOS and NMOS transistors. These variations are within the scope of the invention. For example, in another embodiment, the even transistors 107a, 107c, 108a, and 108c are PMOS transistors and the odd transistors 107b, 107d, 108b, and 108d are NMOS transistors. In still another embodiment, the even transistors 107a, 107c, 108b, and 108d are PMOS transistors and the odd transistors 107b, 107d, 108a, and 108c are NMOS transistors. In still another embodiment, the even transistors 107a, 107b, 108c, and 108d are PMOS transistors and the odd transistors 107c, 107d, 108a, and 108b are NMOS transistors.

FIG. 2F shows another embodiment of a MOSFET transistor structure constructed according to the invention. This embodiment is similar to the embodiment shown in FIG. 2A except that power bus lines 109a, 109b, 110a, and 110b are located between the upper-layer transistor layer 101 (e.g., transistors 107a to 107d) and the lower-layer transistor layer 102 (e.g., transistors 108a to 108d). The upper-layer transistors 107a to 107d are connected to the metal layer 111a to 111d above the transistors using the contacts, such as contacts 113a and 113b, or to the power bus lines 109a and 109b under the transistors using contacts, such as contacts 113c and 113d. The lower-layer transistors 108a to 108d are connected to the metal layer 112a to 112d under the transistors using contacts, such as contacts 113e and 113f, or to the power bus lines 110a and 110b above the transistors using contacts, such as contacts 113g and 113h. The upper-layer transistors 107a to 107d and the lower-layer transistors 108a to 108d are connected using contacts, such as contacts 113i and 113j.

In addition to the two-layer transistor structures shown in the previous embodiments, the structures according to the invention can be applied to single-layer transistor structures as well.

FIG. 2G shows another embodiment of a MOSFET transistor structure constructed according to the invention. This embodiment is similar to the embodiment shown in FIG. 2A except that the transistors 107a to 107d are arranged in one layer (e.g., transistor layer 101) instead of two layers.

FIG. 2G comprises PMOS transistors 107a and 107b and NMOS transistors 107c and 107d. A VDD bus line 109a and a VSS bus line 109b are also shown. The structure comprises metal layers 111a to 111d located above the transistors and metal layers 112a to 112d located below the transistors. The transistors 107a to 107d are connected to the metal layer 111a to 111d above the transistors through contacts, such as contacts 113a and 113b, or to power bus line 109a and 109b through contacts, such as contacts 113c and 113d, or to the metal layers 112a to 112d below the transistors through contacts, such as contacts 113e and 113f.

FIG. 2H shows another embodiment of a MOSFET transistor structure constructed according to the invention. This embodiment is similar to the embodiment shown in FIG. 2G except that power bus lines 110a and 110b are located under the transistors 107a to 107d. The transistors 107a to 107d are connected to the metal layer 111a to 111d above the transistors through contacts, such as contacts 113a and 113b, or to power bus lines 110a and 110b through contacts, such as contacts 113c and 113d, or to the metal layer 112a to 112d under the transistors through contacts, such as contacts 113e and 113f.

FIG. 2I shows another embodiment of a MOSFET transistor structure constructed according to the invention. This embodiment is similar to the embodiment shown in FIG. 2G except that the VDD power bus line 109a and the VSS power bus line 110b are located above and under the transistors 107a to 107d, respectively.

FIG. 2J shows another embodiment of a MOSFET transistor structure according to the invention. This embodiment is similar to the embodiment shown in FIG. 2I except that the PMOS transistors 107a and 107b are only connected to the metal layers 111a to 111b above the transistors through the contacts 113a and 113b, or to the power bus line 110a under the transistors through the contacts 113c and 113d. Also, the NMOS transistors 107c and 107d are only connected to the metal layers 112c to 112d under the transistors through the contacts 113e and 113f, or to the power bus line 109b above the transistors through the contacts 113g and 113h. By using this structure, the number of the metal layer connections to the metal layers 111a to 111d and 112a to 112d are further reduced to one quarter of the connections used in a conventional structure. This aspect increases the pitch of the patterns in the metal layers 111a to 111d and 112a to 112d, which reduces mask cost and process challenges and improves the yield. This structure also allows for wider power bus lines, as shown by bus lines 110a and 109b, to reduce the sheet resistance of the metal bus and improve the current driving capability.

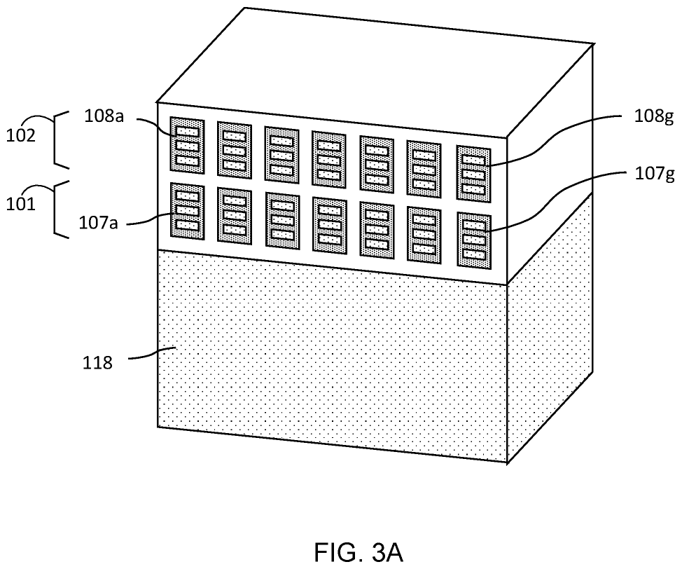

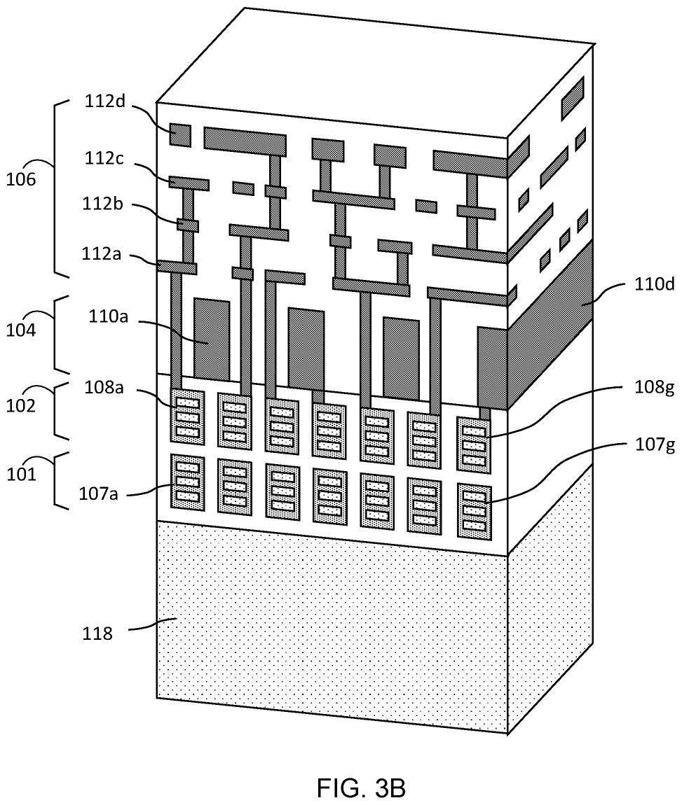

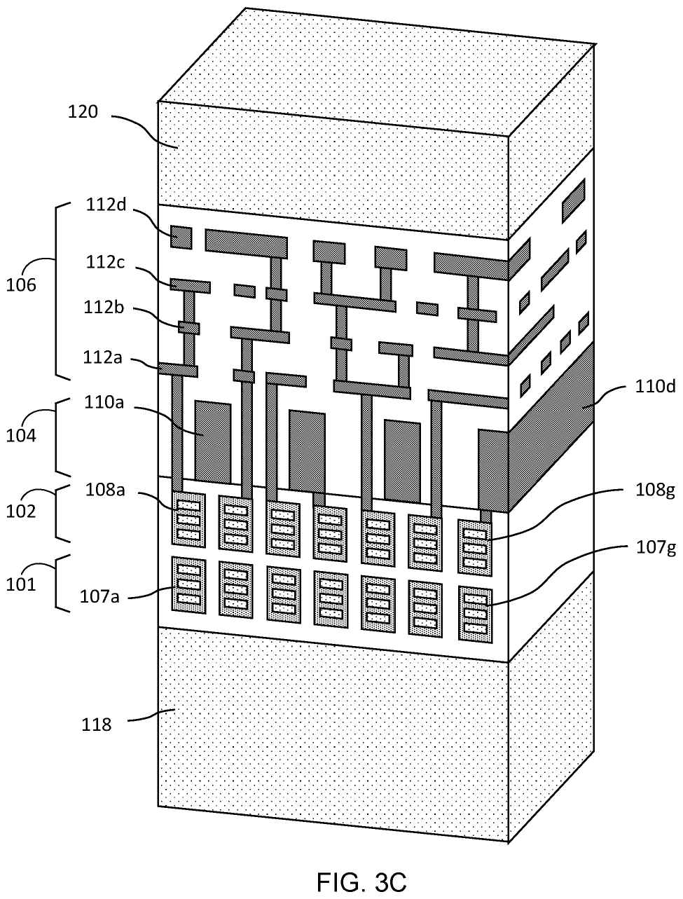

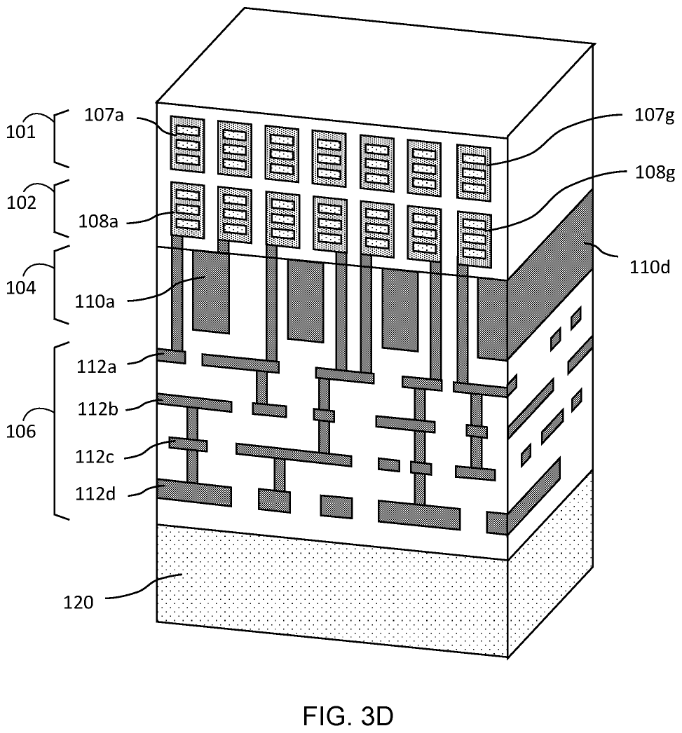

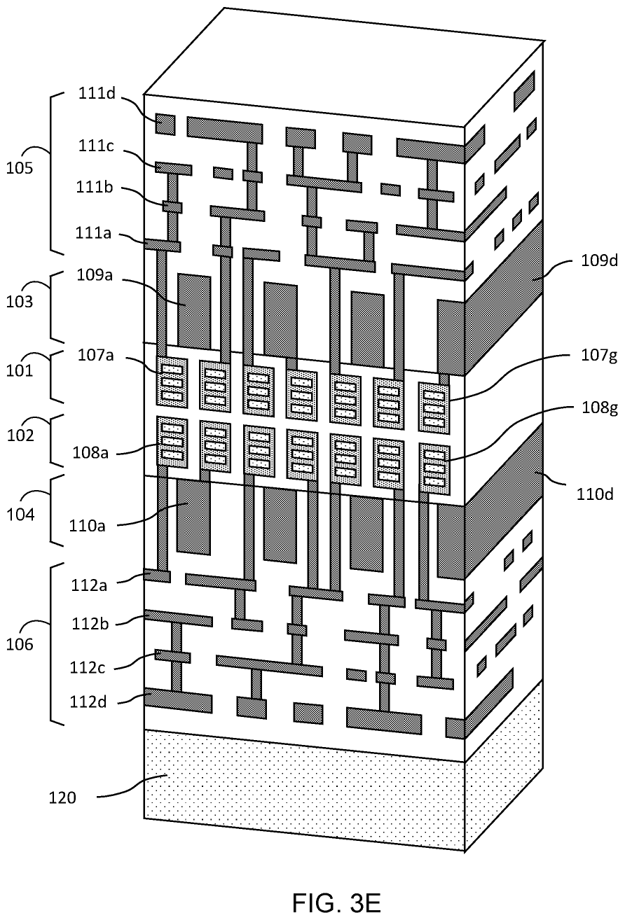

FIGS. 3A-E show embodiments of process steps used to form the transistor structure shown in FIG. 1 according to the invention.

FIG. 3A shows an embodiment of a transistor structure in which transistor layers 101 and 102, such as PMOS transistors 107a to 107g and NMOS transistors 108a to 108g, are formed on top of a substrate 118 of a first wafer. The transistor layers 101 and 102 are formed by using any suitable processes according to the type of transistors. For example, in one embodiment, the PMOS transistors 107a to 107g and the NMOS transistors 108a to 108g are formed by using a multi-bridge channel (MBC) transistor process. For this embodiment, the transistors 107a to 107g and 108a to 108g are formed by alternately depositing multiple semiconductor layers, such as silicon and multiple sacrificial layers, such as silicon germanium (SiGe) on top of the surface of the substrate 118. Then, the multiple semiconductor layers and the sacrificial layers are patterned by lithography steps and etched by using an anisotropic etching process, such as dry etch to form multi-bridge channels, such as 115a to 115c and 116a to 116c shown in FIG. 2A.

After that, the sacrificial layers between the multi-bridge channels are removed by using an isotropic etching process, such as wet etch. Then, a gate dielectric layer, such as high-K material such as hafnium oxide (HfO₂), is formed on the surface of the multi-bridge channels by using thin-film deposition, as shown 117a and 117b in FIG. 2A. After that, a metal layer, such as titanium nitride (TiN) is deposited to form the gates of the PMOS transistors 107a to 107g. A metal layer, such as titanium aluminum (TiAl) is deposited to form the gates of the NMOS transistors 108a to 108g. An insulating layer, such as oxide is deposited between the metal gates of the PMOS transistors 107a to 107g and NMOS transistors 108a to 108g. After that, an insulating layer, such as oxide is deposited to fill the spaces between the transistors to form the structure shown in FIG. 3A.

FIG. 3B shows the transistor structure of FIG. 3A in which a power bus layer 104 that comprises bus lines 110a to 110d are first formed on top of the transistor layers 101 and 102. Then, metal interconnection layer 106 that comprises multiple layers of metal 112a to 112d are formed on top of the power bus layer 104. In one embodiment, the power bus lines 110a to 110d and the metal layers 112a to 112d are formed by using a standard back end of line (BEOL) process. In today's most advanced process, the power bus lines 110a to 110d and the metal layers 112a to 112d are formed by using a damascene or dual-damascene process with low resistance metal, such as copper (Cu). The metal layers 110a to 110d are connected to other parts of the structure by using copper (Cu) vias.

FIG. 3C shows the transistor structure of FIG. 3B in which a dummy wafer 120 is attached (e.g., glued or bonded) on top of the first wafer as shown. FIG. 3C is for illustration only and is not drawn to the scale. The typical thickness of a real wafer is more than 700 micrometers (um). Many wafer bonding processes can be used to attach the dummy wafer 120 to the first wafer. For example, in one embodiment, the dummy wafer 120 is attached by using adhesive bonding, such as by using polymers, epoxies, dry films, polyimides, and UV curable compounds. In addition, other wafer bonding processes, such as anodic, eutectic, fusion, glass frit, metal diffusion, hybrid, or solid liquid inter-diffusion (SLID) may be used.

FIG. 3D shows the transistor structure of FIG. 3C that is flipped 180 degrees and grinded to remove the substrate 118 of the first wafer. The dummy wafer 120 prevents the first wafer from cracking during wafer handling after the grinding process. In one embodiment, the first wafer is grinded by using any suitable standard wafer grinding processes, such as using a diamond-resin bonded grinding wheel to remove the silicon substrate 118 material from the back of the wafer. In another embodiment, the substrate 118 of the first wafer is removed by using chemical-mechanical publishing (CMP) processes.

FIG. 3E shows the transistor structure of FIG. 3D in which a power bus layer 103 that comprises power lines 109a to 109d and a metal layer 105 that comprises multiple metal layers, such as layers 111a to 111d are formed on top of the transistor layer 101. In one embodiment, the power bus lines 109a to 109d and the metal layers 111a to 111d are formed by using a standard back end of line (BEOL) process as described in FIG. 3B. As a result, the structure shown in FIG. 1 is formed.

Thus, in one embodiment, a process for forming a transistor structure is disclosed as describe above. The process comprises forming a transistor layer above a substrate, forming a first power bus layer above of the transistor layer, forming a first interconnection layer above the first power bus layer, rotating the transistor structure 180 degrees so that the substrate is on top of the transistor structure, removing the substrate to expose the transistor layer, forming a second power bus layer above the transistor layer, and forming a second interconnect layer above the second power bus layer.

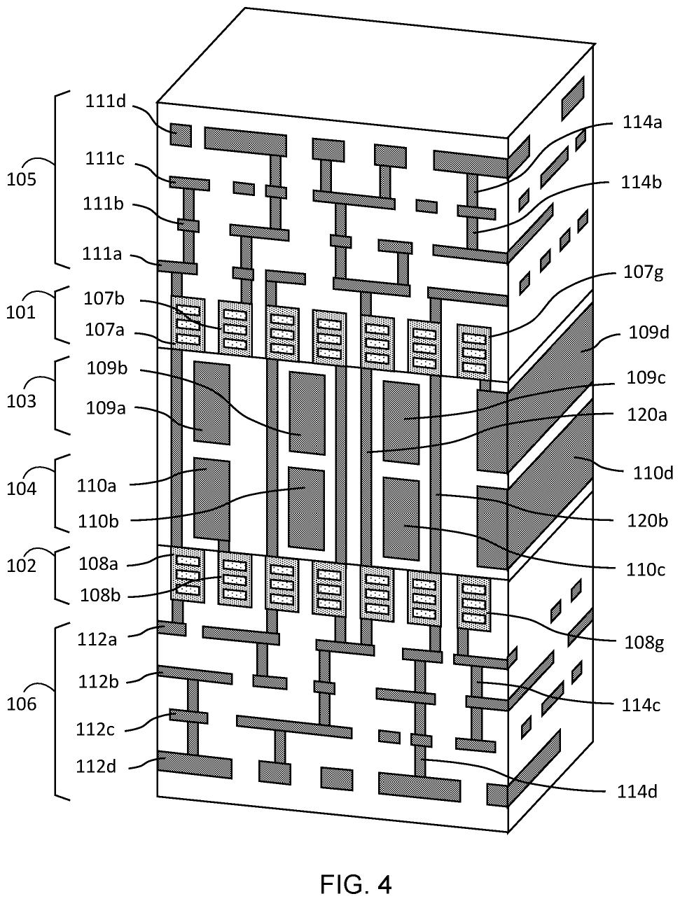

FIG. 4 shows another embodiment of structure having transistors and metal layers similar to the embodiment shown in FIG. 2F according to the invention. For example, in FIG. 3E the power bus layers 103, 104 are above and under the transistor layers 101, 102, and in FIG. 4, the power bus layers 103, 104 are in between the transistor layers 101, 102. It is obvious that the structure shown in FIG. 4 can be formed by using similar process steps to those used to form the structures shown in FIGS. 3A-E. For simplicity, the detailed description for the process steps of this embodiment will not be repeated.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A transistor structure, comprising:
a first transistor layer;
a second transistor layer located under the first transistor layer;
a first power bus layer located above the first transistor layer;
a second power bus layer located under the second transistor layer; and
a first interconnect layer located above the first power bus layer.

2. The transistor structure of claim 1 further comprises a second interconnect layer located under the second power bus layer.

3. The transistor structure of claim 2, wherein the first interconnect layer and the second interconnect layer are formed from metal lines.

4. The transistor structure of claim 3, wherein the first interconnect layer is connected to the first transistor layer by contacts.

5. The transistor structure of claim 3, wherein the second interconnect layer is connected to the second transistor layer by contacts.

6. The transistor structure of claim 1, wherein each of the first and second transistor layers comprise one of NMOS transistors, PMOS transistors, and a combination of NMOS and PMOS transistors.

7. The transistor structure of claim 1, wherein the first transistor layer and the second transistor layer comprise multi-bridge channel (MBC) transistors.

8. The transistor structure of claim 1, wherein the first transistor layer and the second transistor layer comprise FinFET transistors.

9. The transistor structure of claim 1, wherein the first transistor layer and the second transistor layer comprise Forksheet transistors.

10. The transistor structure of claim 1, wherein the first power bus layer and the second power bus layer are formed from metal lines.

11. The transistor structure of claim 1, wherein the first power bus layer and the second power bus layer formed VDD and VSS buses.

12. A transistor structure, comprising:
a first transistor layer;
a second transistor layer located below the first transistor layer;
first and second power bus layers located between the first and second transistor layers;
a first interconnect layer located above the first transistor layer; and
a second interconnect layer located under the second transistor layer.

13. The transistor structure of claim 12, wherein the first power bus layer is above the second power bus layer.

14. The transistor structure of claim 12, wherein the first interconnect layer and the second interconnect layer are formed from metal lines.

15. The transistor structure of claim 14, wherein the first interconnect layer is connected to the first transistor layer by contacts.

16. The transistor structure of claim 14, wherein the second interconnect layer is connected to the second transistor layer by contacts.

17. The transistor structure of claim 12, wherein each of the first and second transistor layers comprise one of NMOS transistors, PMOS transistors, and a combination of NMOS and PMOS transistors.

18. The transistor structure of claim 12, wherein the first power bus layer and the second power bus layer are formed from metal lines.

19. The transistor structure of claim 12, wherein the first power bus layer and the second power bus layer formed VDD and VSS buses.

20. A process for forming a transistor structure, comprising:
forming a transistor layer above a substrate;
forming a first power bus layer above of the transistor layer;
forming a first interconnection layer above the first power bus layer;
rotating the transistor structure 180 degrees so that the substrate is on top of the transistor structure;
removing the substrate to expose the transistor layer;
forming a second power bus layer above the transistor layer; and
forming a second interconnect layer above the second power bus layer.
